(19) United States
(12) Patent Application Publication
(10) Pub. No.: US 2026/0282722 A1
(43) Pub. Date: Sep. 17, 2026

(54) Electronic Device

(71) Applicant: Samsung Display Co., Ltd., Yongin-si (KR)

(72) Inventor: Seong Ji Ko, Yongin-si (KR)

(73) Assignee: Samsung Display Co., Ltd., Yongin-si (KR)

(21) Appl. No.: 19/463,299

(22) Filed: Jan. 29, 2026

(30) Foreign Application Priority Data
Mar. 14, 2025 (KR) 10-2025-0033230

(51) Int. Cl. H10K 59/80; H10K 59/126

(52) U.S. Cl. CPC H10K 59/879; H10K 59/126; H10K 59/873

(57) ABSTRACT

An electronic device including a display panel with improved light efficiency and limited angle of view. The display panel includes multiple layers of high and low refractive index material and patterned surfaces which refracted light in a desired direction.

### CROSS-REFERENCE TO RELATED APPLICATIONS

This application claims priority under 35 U.S.C. § 119 to Korean Patent Application No. 10-2025-0033230 filed on Mar. 14, 2025, in the Korean Intellectual Property Office, the disclosure of which is incorporated by reference herein in its entirety.

### BACKGROUND

Aspects of the present disclosure described herein relate to an electronic device, and more particularly, relate to an electronic device including a light control layer that controls light having an emergence angle of a predetermined angle or more.

With development of the information society, the demand for a display device for displaying an image is increasing in various forms. For example, the display device is applied to various electronic devices such as smartphones, digital cameras, laptop computers, navigation systems, and smart televisions. Further, the display device may be applied to a center information display (CID) disposed on an instrument panel, a center fascia, or a dashboard of a vehicle.

A need for a method of controlling light emitted in a lateral direction is increasing to improve a front luminance factor of the display device.

### SUMMARY

Aspects of the present disclosure provide an electronic device having improved viewing angle limitation characteristics and front light emitting efficiency.

According to an aspect, an electronic device includes a plurality of light emitting parts that emit light, an encapsulation layer that covers the light emitting parts, a lens layer disposed on the encapsulation layer and including a light shielding layer, on which a plurality of openings overlapping the light emitting parts are defined, and a plurality of lenses overlapping the openings, a coating layer that covers the lens layer, and a light control layer disposed between the lens layer and the encapsulation layer and including a plurality of insulating films, wherein the light control layer includes a first low refractive layer, a high refractive layer, and a second low refractive layer that are sequentially arranged on the light emitting parts and are made of organic materials, an upper surface or a lower surface of the high refractive layer includes a plurality of convex patterns, and each of the lenses overlaps two or more of the convex patterns on a plane.

The electronic device according to the present disclosure may further include an inorganic protective film disposed between the high refractive layer and the second low refractive layer, and the convex patterns may be spaced apart from the inorganic protective film, may be defined on the lower surface of the high refractive layer, and may be in contact with the first low refractive layer.

The convex patterns may be spaced apart from the first low refractive layer, may be defined on the upper surface of the high refractive layer, and may be in contact with the second low refractive layer.

A maximum width of each of the lenses may be 10 times or less a maximum width of each of the convex patterns.

A recessed depth of each of the convex patterns may be 0.5 times or less a maximum width of each of the convex patterns.

The light shielding layer may overlap at least some of the convex patterns on a plane.

Each of the lenses may have a refractive index higher than those of the second low refractive layer and the coating layer.

The encapsulation layer may include a first inorganic layer, an organic layer, and a second inorganic layer, and the first low refractive layer may include the same material as the organic layer.

The electronic device according to the present disclosure may further include a sensor layer, and the sensor layer may be disposed between the light control layer and the encapsulation layer.

A refractive index of the high refractive layer may be greater than or equal to 1.63, and refractive indexes of the first low refractive layer, the second low refractive layer, and the coating layer may be smaller than or equal to 1.54.

The light emitting parts may include a first light emitting part and a second light emitting part, and the lenses and the plurality of patterns overlap the first light emitting part on a plane and do not overlap the second light emitting part on a plane.

According to an aspect, an electronic device includes a display panel including a plurality of light emitting parts and an encapsulation layer that covers the light emitting parts, a processor that provides image data to the display panel, a light control layer disposed on the display panel, and a window disposed on the light control layer, wherein the light control layer includes a first low refractive layer, a second low refractive layer disposed on the first low refractive layer, a high refractive layer disposed between the first low refractive layer and the second low refractive layer and having a refractive index higher than those of the first low refractive layer and the second low refractive layer, a light shielding layer which is disposed on the second low refractive layer and in which an opening is defined, a lens overlapping the opening and disposed on an upper surface of the second low refractive layer, and a coating layer that covers the light shielding layer and the lens, an upper surface of one of the first low refractive layer and the high refractive layer includes a plurality of concave or convex patterns, and a maximum width of the lens is greater than a maximum width of each of the patterns.

The patterns may be defined on the upper surface of the first low refractive layer, and each of the patterns may be a concave pattern recessed toward the display panel.

The maximum width of the lens may be 10 times or less a maximum width of the concave pattern.

A recessed depth of the concave pattern may be 0.5 times or less a width of the concave pattern.

The electronic device according to the present disclosure may further include an inorganic film disposed on the high refractive layer.

The patterns may be defined on the upper surface of the high refractive layer, and each of the patterns may be a convex pattern protruding toward the light shielding layer.

The convex pattern may be in contact with the second low refractive layer.

The encapsulation layer may include a first inorganic layer, an organic layer, and a second inorganic layer, and the first low refractive layer may include the same material as the organic layer.

A refractive index of the high refractive layer may be greater than or equal to 1.63, and refractive indexes of the first low refractive layer, the second low refractive layer, and the coating layer may be smaller than or equal to 1.54.

The light emitting parts may include a first light emitting part and a second light emitting part, and the lens and the plurality of patterns overlap the first light emitting part on a plane and do not overlap the second light emitting part on a plane.

### BRIEF DESCRIPTION OF THE FIGURES

The above and other objects and features of the present disclosure will become apparent by describing in detail aspects thereof with reference to the accompanying drawings.

FIG. 1 is a block diagram of an electronic device according to an aspect.

FIG. 2 shows perspective views of electronic devices.

FIG. 3 is a view illustrating the interior of a vehicle in which a display device according to an aspect of the present disclosure is disposed.

FIG. 4 is a schematic view illustrating a viewing angle of an image of a display device according to an aspect of the present disclosure.

FIGS. 5A and 5B are cross-sectional views of a display device according to an aspect of the present disclosure.

FIG. 6 is a schematic diagram of a display device according to an aspect of the present disclosure.

FIG. 7 is a cross-sectional view of a portion of a display device according to an aspect of the present disclosure.

FIG. 8 is a cross-sectional view of the portion of a display device according to an aspect of the present disclosure.

FIG. 9 is a cross-sectional view of the portion of a display device according to an aspect of the present disclosure.

FIG. 10A is a view illustrating the interior of the vehicle in which a display device according to an aspect of the present disclosure is disposed.

FIG. 10B is a view illustrating an image visually recognized from a driver seat when a display device according to an aspect of the present disclosure operates in a first mode.

FIG. 10C is a view illustrating an image visually recognized from a driver seat when a display device according to an aspect of the present disclosure operates in a second mode.

FIG. 11 is an enlarged plan view of a partial area of a display panel according to an aspect of the present disclosure.

FIG. 12 is a cross-sectional view of the portion of a display device according to an aspect of the present disclosure.

FIGS. 13A - 13F are cross-sectional views illustrating steps of manufacturing a display device according to an aspect of the present disclosure.

### DETAILED DESCRIPTION

Since the present disclosure is variously modified and has various forms, aspects thereof will be illustrated in the drawings and will be described herein in detail. However, it should be understood that the present disclosure is not limited to a specific disclosure and includes all changes, equivalents, and substitutes included in the spirit and scope of the present disclosure.

In the specification, the expression that a first component (or an area, a layer, a part, a portion, etc.) is “disposed on”, “connected with” or “coupled to” a second component means that the first component is directly disposed on/connected with/coupled to the second component or means that a third component is interposed therebetween.

The same reference numerals refer to the same components. Further, in the drawings, the thickness, the ratio, and the dimension of components are exaggerated for effective description of technical contents. The term “and/or” includes all combinations of one or more components that may be defined by associated components.

Although the terms “first”, “second”, etc. may be used to describe various components, the components should not be limited by the terms. The terms are only used to distinguish one component from another component. For example, without departing from the right scope of the present disclosure, a first component may be referred to as a second component, and similarly, the second component may be also referred to as the first component. Singular expressions include plural expressions unless clearly otherwise indicated in the context.

Also, the terms “under”, “below”, “on”, “above”, etc. are used to describe the correlation of components illustrated in drawings. The terms that are relative in concept are described based on a direction illustrated in drawings.

It will be understood that the terms “include”, “comprise”, “have”, etc. specify the presence of features, numbers, steps, operations, elements, or components, described in the specification, or a combination thereof, and do not exclude in advance the presence or additional possibility of one or more other features, numbers, steps, operations, elements, or components or a combination thereof.

In the specification, the wording “directly disposed” may mean that there is no layer, no film, no area, no plate, and the like added between a part such as a layer, a film, an area, and a plate, and other parts. For example, the wording “directly disposed” may mean that an additional member such as an adhesive member is not disposed between two layers or two members.

Unless otherwise defined, all terms (including technical terms and scientific terms) used in the specification have the same meaning as commonly understood by those skilled in the art to which the present disclosure belongs. Further, terms such as terms defined in the dictionaries commonly used should be interpreted as having a meaning consistent with the meaning in the context of the related technology and should not be interpreted in overly ideal or overly formal meanings unless explicitly defined herein.

Hereinafter, a display device according to an aspect will be described with reference to the accompanying drawings.

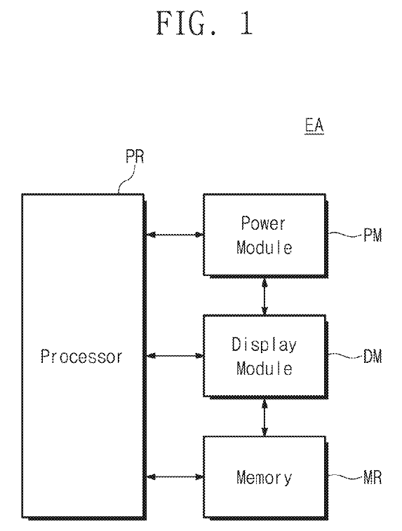

FIG. 1 is a block diagram of an electronic device according to an aspect.

Referring to FIG. 1, an electronic device EA according to an aspect may include a display module DM, a processor PR, a memory MR, and a power module PM.

The processor PR may include at least one of a central processing unit (CPU), an application processor (AP), a graphic processing unit (GPU), a communication processor (CP), an image signal processor (ISP), and a controller.

Data information required for operating the processor PR or the display module DM may be stored in the memory MR. When the processor PR executes an application stored in the memory MR, an image data signal and/or an input control signal may be transmitted to the display module DM, and the display module DM may process the received signal and output image information through a display screen. The display module DM may include a display panel that displays an image.

The power module PM may include a power conversion module. The power conversion module may be a power supply module such as a power adapter or a battery device and convert power supplied by the power supply module to generate power required for operating the electronic device EA.

At least one of components of the electronic device EA may be included in a display module according to an aspect, which will be described below, and a display device according to an aspect including the same. Further, some of individual modules functionally included inside one module may be included inside the display device, and the others thereof may be provided separately from the display device. For example, the display device may include the display module DM, and the processor PR, the memory MR, and the power module PM may be provided in the form of other devices in the electronic device EA rather than the display device.

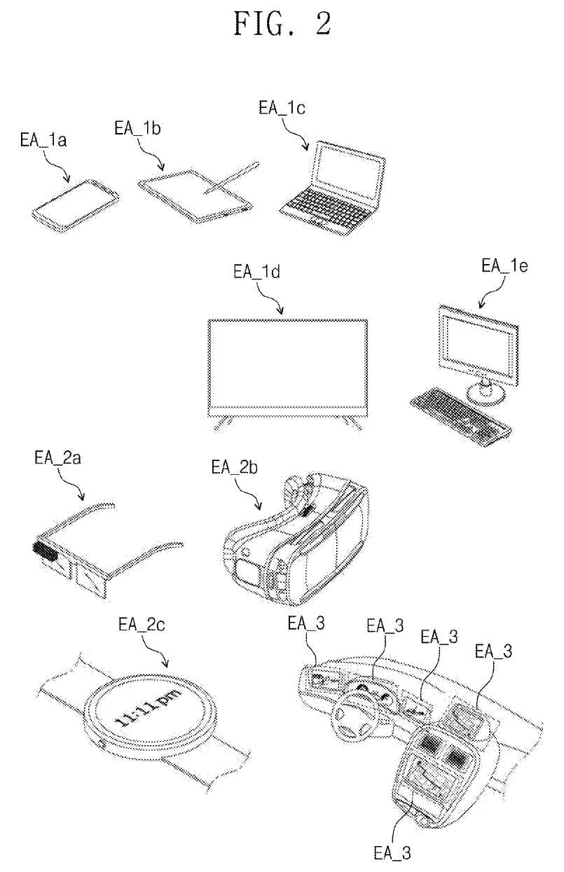

FIG. 2 illustrates various electronic devices that may include a display module according to an aspect.

Referring to FIG. 2, various electronic devices including the display module according to an aspect may include an image display electronic device such as a smartphone EA_1a, a tablet PC EA_1b, a laptop computer EA_1c, a television (TV) EA_1d, and a desk monitor EA_1e, a wearable electronic device such as a smart glasses EA_2a, a head mounted display EA_2b, and a smart watch EA_2c, and a vehicle electronic device EA_3 such as an instrument panel, a center fascia, a center information display (CID) disposed on a dashboard, and a room mirror display of a vehicle.

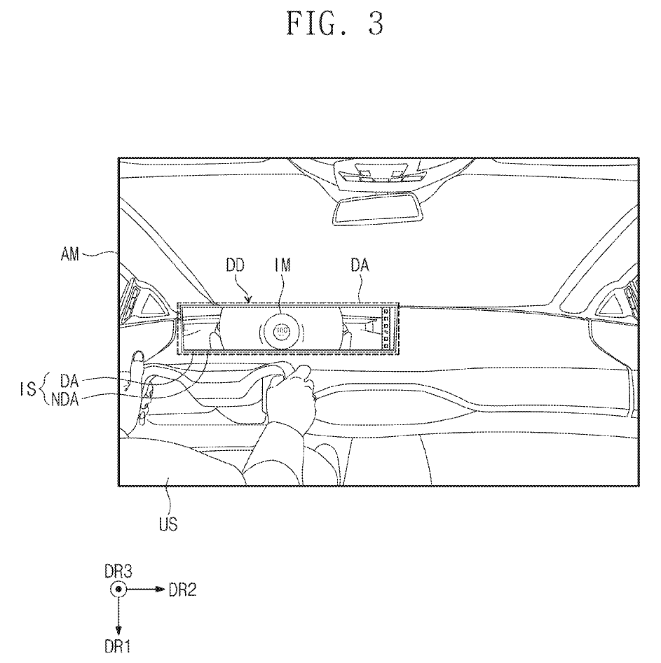

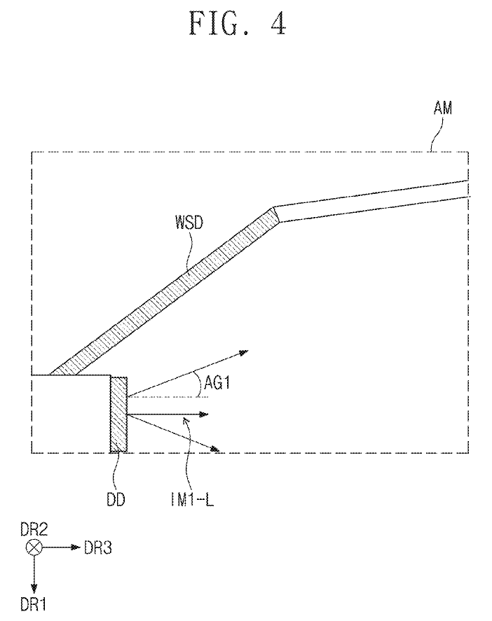

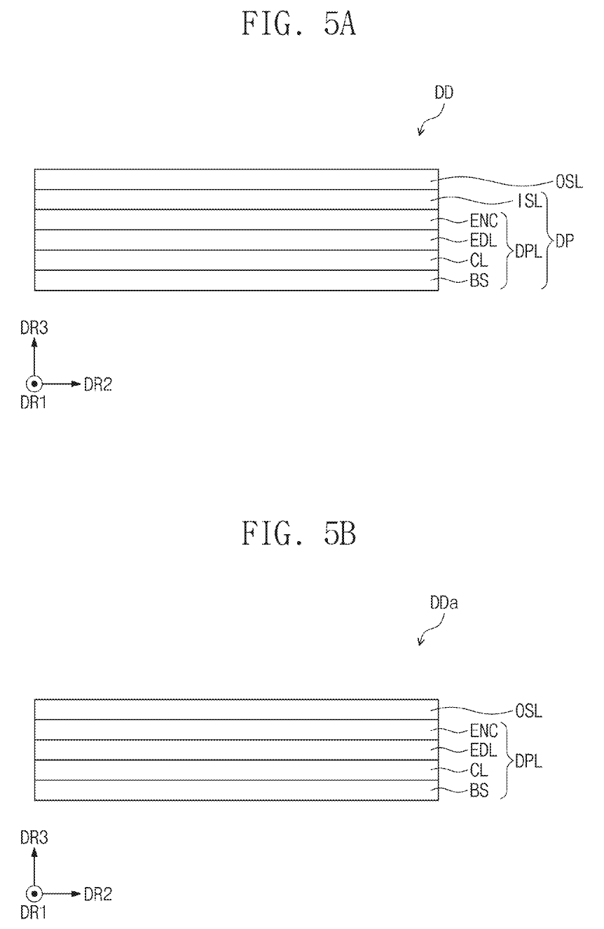

FIG. 3 is a view illustrating an interior of a vehicle AM in which a display device DD according to an aspect of the present disclosure is disposed. FIG. 4 is a schematic view illustrating a viewing angle AG in a vertical direction of an image IM of the display device DD according to an aspect of the present disclosure.

Referring to FIG. 3, the display device DD according to an aspect of the present disclosure may be disposed inside the vehicle AM. The display device DD may be a device that is activated according to an electric signal. The display device DD may be applied to electronic devices such as mobile phones, tablets, smart watches, laptops, computers, and smart televisions. The display device DD may be disposed inside the vehicle AM to provide various pieces of information to a driver US.

The display device DD may display the image IM on a display surface IS parallel to a first direction DR1 and a second direction DR2. The display surface IS on which the image IM is displayed may correspond to a front surface of the display device DD. The image IM may include a still image as well as a dynamic image. A normal direction of the display surface IS, that is, a thickness direction of the display device DD, is indicated by a third direction DR3. Hereinafter, front surfaces (or upper surfaces) and rear surfaces (or lower surfaces) of layers or units, which will be described below, are distinguished by the third direction DR3.

In the specification, the first direction DR1 may be referred to as a vertical direction, the second direction DR2 may be referred to as a left-right direction, and the third direction DR3 may be referred to as a thickness direction.

The display surface IS of the display device DD may be divided into a display area DA and a non-display area NDA. The display area DA may be an area on which the image IM is displayed. A user visually recognizes the image IM through the display area DA. In an aspect, it is illustrated that the display area DA has a rectangular shape. However, this is illustrated by way of example, the display area DA may have various shapes, and the present disclosure is not limited to any particular shape.

The non-display area NDA may be adjacent to the display area DA. The non-display area NDA may have a predetermined color. The non-display area NDA may surround the display area DA. Accordingly, a shape of the display area DA may be substantially defined by the non-display area NDA. However, this is illustrated by way of example, and the non-display area NDA may be disposed adjacent to only one side of the display area DA or may be omitted. The display device DD according to an aspect of the present disclosure may or may not include non-display area NDA.

The display area DA may be disposed at a position facing a driver seat, and may provide the image IM required for driving to the driver US who performs driving. For example, the image IM may display speed information, vehicle state information, vehicle internal operation information, and the like.

Referring to FIG. 4, in an aspect, the viewing angle AG of the display area DA in the vertical direction DR1 may be limited. That is, a light IM1-L provided in the display area DA may not be visually recognized at an angle that is greater than the viewing angle AG. A path of the light IM1-L provided in the display area DA in the vertical direction DR1 may be limited and thus may not reach a windshield WSD of the vehicle AM. Thus, the amount of the light IM1-L that is provided in the display area DA and reaches the windshield WSD of the vehicle AM may be reduced. Thus, a problem that the light IM1-L is reflected from the windshield of the vehicle and visually recognized by the driver may be improved, thereby securing safety of the driver.

FIGS. 5A and 5B are cross-sectional views of a display device DD according to an aspect of the present disclosure.

Referring to FIG. 5A, the display device DD may include a display panel DP and a light control layer OSL. A protective film, a window, or a functional coating layer providing a front surface of the display device DD may be further disposed on the light control layer OSL.

The display panel DP may include a display layer DPL and a sensor layer ISL.

The display layer DPL may include a base layer BS, a circuit layer CL, a light emitting element layer EDL, and an encapsulation layer ENC. The display layer DPL may be a component that substantially generates an image. The display layer DPL may be a light emitting display layer. For example, the display layer DPL may be an organic light emitting display layer, an inorganic light emitting display layer, an organic-inorganic light display layer, a quantum dot display layer, a micro-light emitting diode (LED) display layer, or a nano-LED display layer.

The sensor layer ISL may sense an external input applied from an external unit. The external input may be an input of the user. The input of the user may include various types of external inputs such as a portion of the user’s body, light, heat, a pen, and pressure. The sensor layer ISL may be referred to as a sensor, an input sensing layer, or an input sensing panel. The sensor layer ISL may be formed through a continuous process together with the display layer DPL and may be directly disposed on the display layer DPL. However, the present disclosure is not particularly limited thereto. For example, the sensor layer ISL may be coupled to the display layer DPL through an adhesive layer.

The light control layer OSL may control a path of light provided from the display layer DPL. The light control layer OSL may include a structure for controlling the path of the light. The light control layer OSL may be disposed on the sensor layer ISL. The light control layer OSL may be formed through a continuous process together with the display layer DPL and the sensor layer ISL and may be directly disposed on the sensor layer ISL. However, the present disclosure is not particularly limited thereto. For example, the light control layer OSL may also be coupled to the sensor layer ISL through an adhesive layer.

Referring to FIG. 5B, a display device DDa according to an aspect may include the display layer DPL and the light control layer OSL. Compared with FIG. 5A, a display device DDa of FIG. 5B may not include the sensor layer ISL. The light control layer OSL may be formed through a continuous process together with the display layer DPL and may be directly disposed on the display layer DPL. However, the present disclosure is not particularly limited thereto.

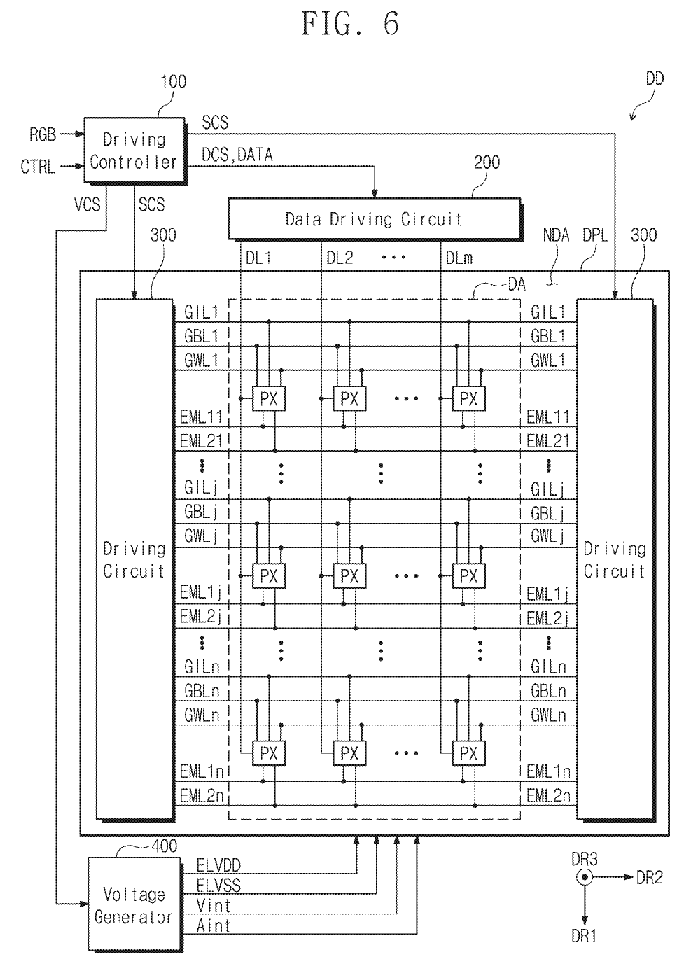

FIG. 6 is a schematic diagram of the display device DD according to an aspect of the present disclosure.

Referring to FIG. 6, the display device DD may further include a driving controller 100 for driving the display layer DPL and a panel driver. As an example of the present disclosure, the panel driver may include a data driving circuit 200 (or a data driver), driving circuits 300, and a voltage generator 400.

The display layer DPL may include the display area DA and the non-display area NDA. The display layer DPL may include a plurality of pixels PX arranged in the display area DA. Each of the plurality of pixels PX includes at least one light emitting element and a pixel driving circuit that controls light emission of a light emitting element ED. The pixel driving circuit may include one or more transistors and one or more capacitors.

The display layer DPL may further include initialization scan lines GIL1 to GILn, write scan lines GWL1 to GWLn, black scan lines GBL1 to GBLn, first light emitting control lines EML11 to EML1n, second light emitting control lines EML21 to EML2n, and data lines DL1 to DLm. In an aspect of the present disclosure, the display layer DPL may further include other third light emitting control lines.

The driving controller 100 receives an image signal RGB and a control signal CTRL. The driving controller 100 generates an image data signal DATA obtained by converting a data format of the image signal RGB such that the image data signal DATA satisfies an interface specification with the data driving circuit 200. The driving controller 100 may output a first control signal SCS, a second control signal DCS, and a third control signal VCS.

The data driving circuit 200 receives the second control signal DCS and the image data signal DATA from the driving controller 100. The data driving circuit 200 converts the image data signal DATA into data signals and outputs the data signals to the data lines DL1 to DLm. The data signals are analog voltages corresponding to a gradation value of the image data signal DATA. The data lines DL1 to DLm may be arranged in the second direction DR2, and each of the data lines DL1 to DLm may extend in the first direction DR1.

The driving circuit 300 may be disposed in the non-display area NDA of the display layer DPL, but the present disclosure is not particularly limited thereto. For example, at least a portion of the driving circuit 300 may be disposed in the display area DA. The driving circuits 300 may include transistors formed through the same process as the pixel driving circuit.

The driving circuit 300 may receive the first control signal SCS and output a scan signal or a light emitting control signal to the initialization scan lines GIL1 to GILn, the write scan lines GWL1 to GWLn, the black scan lines GBL1 to GBLn, the first light emitting control lines EML11 to EML1n, and the second light emitting control lines EML21 to EML2n.

The driving circuit 300 may be provided as the plurality of driving circuits 300. For example, the plurality of driving circuits 300 may be spaced apart from each other with the display area DA interposed therebetween. The initialization scan lines GIL1 to GILn, the write scan lines GWL1 to GWLn, the black scan lines GBL1 to GBLn, the first light emitting control lines EML11 to EML1n, and the second light emitting control lines EML21 to EML2n may be electrically connected to the driving circuits 300 and receive signals from the driving circuits 300. For example, the one initialization scan line GIL1, the one write scan line GWL1, the one black scan line GBL1, the one first light emitting control line EML11, and the one second light emitting control line EML21 may receive the same signal from the two driving circuits 300. However, this is merely an example, and one of the two driving circuits 300 illustrated in FIG. 6 may be omitted.

Each of the driving circuits 300 may include a scan driving circuit connected to the initialization scan lines GIL1 to GILn, the write scan lines GWL1 to GWLn, and the black scan lines GBL1 to GBLn and a light emitting control driving circuit connected to the first light emitting control lines EML11 to EML1n and the second light emitting control lines EML21 to EML2n. In an aspect of the present disclosure, the scan driving circuit and the light emitting control driving circuit may be spaced apart from each other with the display area DA interposed therebetween.

Each of the initialization scan lines GIL1 to GILn, the write scan lines GWL1 to GWLn, the black scan lines GBL1 to GBLn, the first light emitting control lines EML11 to EML1n, and the second light emitting control lines EML21 to EML2n may extend in the second direction DR2, and the initialization scan lines GIL1 to GILn, the write scan lines GWL1 to GWLn, the black scan lines GBL1 to GBLn, the first light emitting control lines EML11 to EML1n, and the second light emitting control lines EML21 to EML2n may be spaced apart from each other in the first direction DR1.

Each of the plurality of pixels PX may be electrically connected to three scan lines, two light emitting control lines, and one data line. For example, as illustrated in FIG. 6, the pixels in a first row may be connected to the scan lines GIL1, GWL1, and GBL1, and the first and second light emitting control lines EML11 and EML21. The pixels in a first column may be connected to the data line DL1. Further, the pixels in a j^{th} row may be connected to the scan lines GILj, GWLj, and GBLj and the first and second light emitting control lines EML1j and EML2j.

The voltage generator 400 generates voltages required for operating the display panel DP. In an aspect, the voltage generator 400 may generate a first driving voltage ELVDD, a second driving voltage ELVSS, a first initialization voltage Vint, and a second initialization voltage Aint.

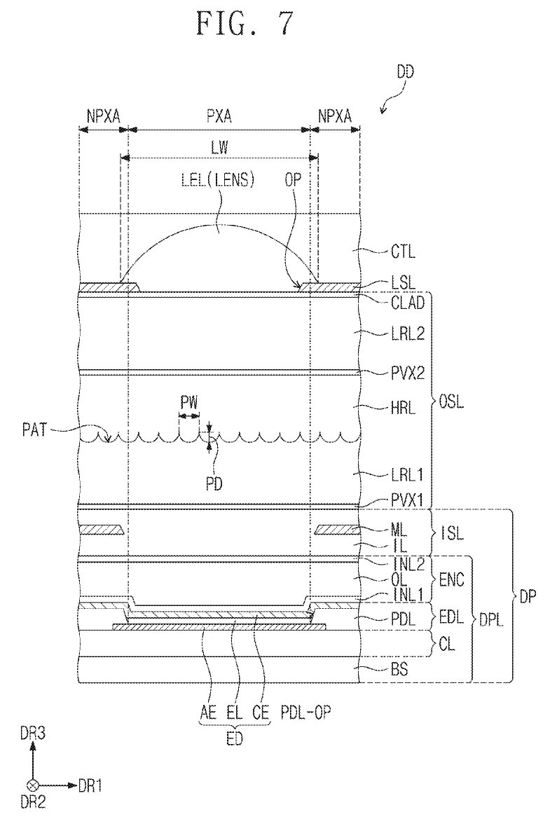

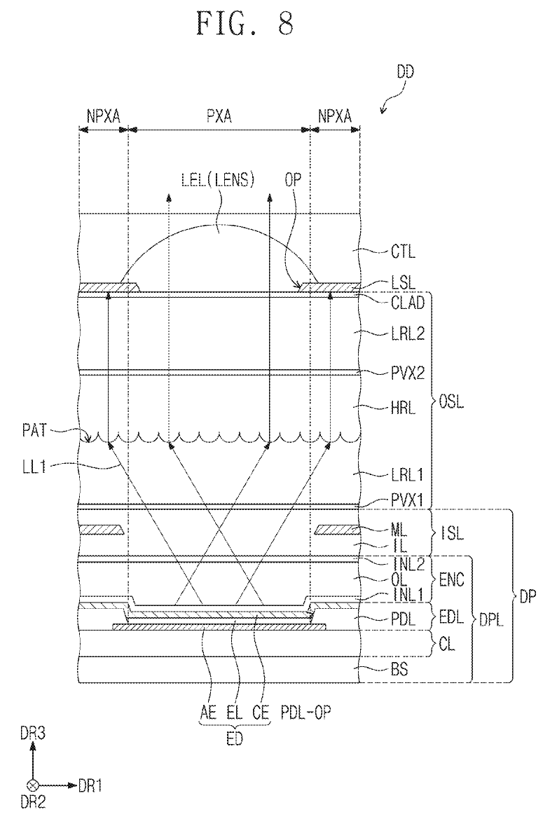

FIG. 7 is a cross-sectional view of a portion of a display device according to an aspect of the present disclosure. FIG. 8 is a cross-sectional view of the portion of a display device according to an aspect of the present disclosure.

Referring to FIG. 7, the display device DD may include the display panel DP, the light control layer OSL, a light shielding layer LSL, a lens layer LEL, and a coating layer CTL.

The display panel DP may include the display layer DPL and the sensor layer ISL. As described above, in the display panel DP, the sensor layer ISL may be omitted.

The display layer DPL may include the base layer BS, the circuit layer CL, the light emitting element layer EDL, and the encapsulation layer ENC.

The base layer BS may be a member that provides a base surface on which the circuit layer CL is disposed. The base layer BS may include a synthetic resin layer. The synthetic resin layer may be a polyimide-based resin layer. The material of the base layer BS is not particularly limited thereto. In addition, the base layer BS may include a glass substrate, a metal substrate, an organic/inorganic composite material substrate, or the like.

The display layer DPL may further include an inorganic layer (not illustrated) on an upper surface of the base layer BS. The inorganic layer may include at least one of an aluminum oxide, a titanium oxide, a silicon oxide, a silicon nitride, a silicon oxy nitride, a zirconium oxide, and a hafnium oxide. The inorganic layer may be formed in multiple layers. The multi-layered inorganic layers may constitute a barrier layer and/or a buffer layer.

The circuit layer CL may be disposed on the base layer BS. A semiconductor pattern may be disposed in the circuit layer CL. The semiconductor pattern may include polysilicon. However, the present disclosure is not limited thereto, and the semiconductor pattern may include amorphous silicon, low-temperature polycrystalline silicon, or an oxide semiconductor. The circuit layer CL may further include a plurality of insulating layers. The plurality of insulating layers may cover the semiconductor pattern. Some of the plurality of insulating layers may be an inorganic layer and the others thereof may be an organic layer. When the insulating layer is an inorganic layer, the insulating layer may include, for example, at least one of an aluminum oxide, a titanium oxide, a silicon oxide, a silicon nitride, a silicon oxy nitride, a zirconium oxide, and a hafnium oxide.

The light emitting element layer EDL may be disposed on the circuit layer CL. The light emitting element layer EDL may include the light emitting element ED and a pixel defining film PDL. For example, the light emitting element layer EDL may include an organic light emitting material, an inorganic light emitting material, an organic-inorganic light emitting material, a quantum dot, a quantum rod, a micro light emitting diode (LED), or a nano LED. Hereinafter, it will be described that the light emitting element ED is an organic light emitting element, but the present disclosure is not particularly limited thereto.

The light emitting element ED may include a first electrode AE, a light emitting layer EL, and a second electrode CE.

The first electrode AE may be disposed on the circuit layer CL. The first electrode AE may be electrically connected to the semiconductor pattern of the circuit layer CL. The first electrode AE is conductive. The first electrode AE may be formed of a metal material, a metal alloy, or a conductive compound. The first electrode AE may be an anode or a cathode. However, an aspect is not limited thereto. Further, the first electrode AE may be a pixel electrode. The first electrode AE may be a transmissive electrode, a semi-transmissive electrode, or a reflective electrode. The first electrode AE may include at least one selected from Ag, Mg, Cu, Al, Pt, Pd, Au, Ni, Nd, Ir, Cr, Li, Ca, LiF, Mo, Ti, W, In, Sn, and Zn, a compound of two or more selected therefrom, a mixture of two or more selected therefrom, or an oxide thereof.

When the first electrode AE is a transmissive electrode, the first electrode AE may include a transparent metal oxide, for example, an indium tin oxide (ITO), an indium zinc oxide (IZO), a zinc oxide (ZnO), an indium tin zinc oxide (ITZO), or the like. When the first electrode AE is a semi-transmissive electrode or a reflective electrode, the first electrode AE may include Ag, Mg, Cu, Al, Pt, Pd, Au, Ni, Nd, Ir, Cr, Li, Ca, LiF/Ca (a laminated structure of LiF and Ca), LiF/Al (a laminated structure of LiF and Al), Mo, Ti, W, or a compound or mixture thereof (e.g., a mixture of Ag and Mg). Alternatively, the first electrode AE may have a multi-layer structure including a reflective film or a semi-transmissive film formed of the above material and a transparent conductive film formed of an indium tin oxide (ITO), an indium zinc oxide (IZO), a zinc oxide (ZnO), and an indium tin zinc oxide (ITZO). For example, the first electrode AE may have a three-layer structure of ITO/Ag/ITO, but the present disclosure is not limited thereto. Further, an aspect is not limited thereto, and the first electrode AE may include the above-described metal materials, a combination of two or more metal materials selected from the above-described metal materials, an oxide of the above-described metal materials, or the like.

The pixel defining film PDL may be disposed on the circuit layer CL, and a light emitting opening PDL-OP may be defined in the pixel defining film PDL. The pixel defining film PDL may cover at least a portion of the first electrode AE and expose the remaining portion of the first electrode AE through the light emitting opening PDL-OP.

The display area DA (see FIG. 1) may include a light emitting area PXA and a non-light emitting area NPXA adjacent to the light emitting area PXA. The non-light emitting area NPXA may surround the light emitting area PXA. In an aspect, the light emitting area PXA may be defined to correspond to an area of the first electrode AE exposed by the light emitting opening PDL-OP.

The light emitting layer EL may be disposed on the first electrode AE. The light emitting layer EL may be disposed in an area corresponding to the light emitting opening PDL-OP. That is, the light emitting layer EL may be formed separately from the respective pixels PX. When the light emitting layer EL is formed separately from the respective pixels, each of the light emitting layers EL may emit light having at least one color of red, green, and blue. However, the present disclosure is not limited thereto, and the light emitting layers EL may be connected to the pixels and may be provided commonly. In this case, the light emitting layer EL may also provide blue light or white light.

The second electrode CE may be disposed on the light emitting layer EL. The second electrode CE may have an integral shape and may be disposed in the plurality of pixels in common. The second electrode CE may be a cathode or an anode, but an aspect is not limited thereto. For example, when the first electrode AE is an anode, the second electrode CE may be a cathode, or when the first electrode AE is a cathode, the second electrode CE may be an anode. A material of the second electrode CE may include the materials described above in the first electrode AE.

Although not illustrated, a hole control layer may be disposed between the first electrode AE and the light emitting layer EL. The hole control layer may be commonly disposed in the light emitting area PXA and the non-light emitting area NPXA. The hole control layer may include a hole transport layer and may further include a hole injection layer. An electron control layer may be disposed between the light emitting layer EL and the second electrode CE. The electron control layer may include an electron transport layer and may further include an electron injection layer. The hole control layer and the electron control layer may be commonly provided to the plurality of pixels using an open mask.

The encapsulation layer ENC may be disposed on the light emitting element layer EDL. The encapsulation layer ENC may include a first inorganic layer INL1, an organic layer OL, and a second inorganic layer INL2 that are sequentially laminated, but layers constituting the encapsulation layer ENC are not limited thereto.

The inorganic layers INL1 and INL2 may protect the light emitting element layer EDL from moisture and oxygen, and the organic layer OL may protect the light emitting element layer EDL from foreign substances such as dust particles. The inorganic layers INL1 and INL2 may include a silicon nitride layer, a silicon oxy nitride layer, a silicon oxide layer, a titanium oxide layer, an aluminum oxide layer, or the like. The organic layer OL may include an acryl-based organic material, but the present disclosure is not limited thereto.

The sensor layer ISL may include at least one conductive layer ML and at least one insulating layer IL. In FIG. 7, it is illustrated that the conductive layer ML is inserted into the insulating layer IL, but this is illustrated by way of example for easy description, and the conductive layer ML may be disposed on or under the insulating layer IL or disposed between a plurality of insulating layers IL, and the present disclosure is not limited to any particular arrangement of conductive layer ML and insulating layer IL. The conductive layer ML may have a single-layer or multi-layer structure. The conductive layer having a single-layer structure may include a metal layer or a transparent conductive layer. The metal layer may include molybdenum, silver, titanium, copper, aluminum, or alloys thereof.

The transparent conductive layer may include transparent conductive oxide, such as an indium tin oxide (ITO), an indium zinc oxide (IZO), a zinc oxide (ZnO), or an indium zinc tin oxide (IZTO). In addition, the transparent conductive layer may include a conductive polymer such as poly(3,4-ethylenedioxythiophene) (PEDOT), metal nanowire, graphene, or the like. The conductive layer having a multi-layer structure may include metal layers. The metal layers may have, for example, a three-layer structure of titanium/aluminum/titanium. The conductive layer having a multi-layer structure may include at least one metal layer and at least one transparent conductive layer. The metal layer may have a mesh shape in which openings overlapping the light emitting area PXA are defined. Accordingly, interference between light emitted from the light emitting element ED and the metal layer may be minimized. However, the present disclosure is not limited thereto.

The insulating layer may include an inorganic film. The inorganic film may include at least one of an aluminum oxide, a titanium oxide, a silicon oxide, a silicon nitride, a silicon oxy nitride, a zirconium oxide, and a hafnium oxide. The insulating layer may include an organic film. The organic film may include at least one of an acryl-based resin, a methacrylate-based resin, a polyisoprene-based resin, a vinyl-based resin, an epoxy-based resin, a urethane-based resin, a cellulose-based resin, a siloxane-based resin, a polyimide-based resin, a polyamide-based resin, and a perylene-based resin.

The light control layer OSL may be disposed between the encapsulation layer ENC and the lens layer LEL. The light control layer OSL may include a plurality of insulating films. Each of the insulating films may be optically transparent. The light control layer OSL may include a first low refractive layer LRL1, a second low refractive layer LRL2, a high refractive layer HRL, a first inorganic protective film PVX1, a second inorganic protective film PVX2, and a third inorganic protective film CLAD.

The first low refractive layer LRL1 may be disposed on the display panel DP. The first low refractive layer LRL1 may include an organic material. A refractive index of the first low refractive layer LRL1, which is measured at a wavelength of 632 nm, may be smaller than or equal to 1.54. The first low refractive layer LRL1 may include the same material as the organic layer OL of the encapsulation layer ENC.

In an aspect, the first inorganic protective film PVX1 may be disposed between the display panel DP and the first low refractive layer LRL1. The first inorganic protective film PVX1 may include an inorganic material. For example, the first inorganic protective film PVX1 may include a silicon oxide, a silicon nitride, or a transparent conductive oxide.

The second low refractive layer LRL2 may be disposed on the first low refractive layer LRL1. The second low refractive layer LRL2 may include an organic material. A refractive index of the second low refractive layer LRL2, measured at a wavelength of 632 nm, may be smaller than or equal to 1.54. The second low refractive layer LRL2 may include the same material as the organic layer OL of the encapsulation layer ENC.

The high refractive layer HRL may be disposed between the first low refractive layer LRL1 and the second low refractive layer LRL2. The high refractive layer HRL may include an organic material. A refractive index of the high refractive layer HRL, measured at a wavelength of 632 nm, may be greater than or equal to 1.63. In detail, the high refractive layer HRL may include an organic material having a refractive index higher than that of the organic layer OL of the encapsulation layer ENC and the first low refractive layer LRL1.

Referring to FIG. 7, a plurality of patterns PAT may be defined on an upper surface of the first low refractive layer LRL1. Each of the patterns PAT may be a concave pattern recessed in a direction toward the display panel DP (or an opposite direction to the third direction DR3). In an aspect, since the high refractive layer HRL is in contact with the first low refractive layer LRL1, a lower surface of the high refractive layer HRL may include the convex patterns PAT. That is, the concave pattern PAT defined on the upper surface of the first low refractive layer LRL1 may correspond to the convex pattern PAT defined on the lower surface of the high refractive layer HRL.

A depth PD (hereinafter, referred to as a depth of the pattern PAT) of the pattern PAT recessed in an opposite direction to the third direction DR3 may be smaller than a maximum width PW of the pattern PAT. For example, the depth PD of the pattern PAT may be 0.5 times or less the maximum width PW of the pattern PAT. When the depth PD of the pattern PAT is formed to be smaller than the maximum width PW of the pattern PAT, a curvature of the pattern PAT formed on a boundary surface between the first low refractive layer LRL1 and the high refractive layer HRL in an opposite direction to the third direction DR3 may be reduced. As a result, optical distortion may be reduced, and light loss may be minimized.

In an aspect, the second inorganic protective film PVX2 (or an inorganic film) may be disposed between the high refractive layer HRL and the second low refractive layer LRL2. By inserting the second inorganic protective film PVX2 between the high refractive layer HRL and the second low refractive layer LRL2, light reflection between the high refractive layer HRL and the second low refractive layer LRL2 may be minimized and transmission efficiency may be increased. The patterns PAT may be defined to be spaced apart from the second inorganic protective film PVX2.

The light shielding layer LSL may be disposed on the light control layer OSL. An opening OP that vertically overlaps the light emitting element ED, i.e. overlaps when viewed in the third direction DR3, may be defined in the light shielding layer LSL. The light shielding layer LSL may vertically overlap at least some of the patterns PAT.

The material constituting the light shielding layer LSL is not particularly limited as long as the material absorbs light. The light shielding layer LSL is a layer having a black color, and in an aspect, the light shielding layer LSL may include a black coloring agent. The black coloring agent may include a black dye and a black pigment. The black coloring agent may include carbon black, a metal such as chromium, or an oxide thereof.

In an aspect, the third inorganic protective film CLAD may be disposed between the second low refractive layer LRL2 and the light shielding layer LSL. The third inorganic protective film CLAD may include a transparent inorganic material. For example, the third inorganic protective film CLAD may include a silicon oxide, a silicon nitride, or a transparent conductive oxide.

The lens layer LEL may be disposed on the light control layer OSL. The lens layer LEL may include a lens LENS that overlaps the opening OP defined in the light shielding layer LSL. In an aspect, the lens LENS may be a convex lens. The lens LENS may have a refractive index higher than those of the second low refractive layer LRL2 and the coating layer CTL, which will be described below. For example, a refractive index of the lens LENS, measured at a wavelength of 632 nm, may be greater than or equal to 1.63. As the lens layer LEL may be formed on the second low refractive layer LRL2, light condensed on a front surface by the pattern PAT may be additionally condensed once again, and thus condensing efficiency may be further improved.

The lens LENS may vertically overlap the plurality of patterns PAT. A maximum width LW of the lens LENS may be greater than the maximum width PW of each of the patterns PAT. In the specification, the term “maximum width” may mean a maximum distance measured in the first direction DR1 on a cross section. In detail, the maximum width LW of the lens LENS may be in a range of about 20 μm to 30 μm, and the maximum width PW of the pattern PAT may be in a range of about 2 μm to 3 μm. The maximum width LW of the lens LENS may be 10 times or less the maximum width PW of each of the patterns PAT. When the maximum width LW of the lens LENS is formed to be 10 times or less the maximum width PW of each of the patterns PAT, process stability may be secured in a process of forming the light control layer OSL and the lens layer LEL, in the sense that the shapes of the lens and the patterns can be uniformly implemented during the formation process. Further, as the maximum width PW of each of the patterns PAT defined on an upper surface of the high refractive layer HRL becomes smaller, the ratio of light traveling in a diagonal direction among the light emitted from the light emitting element ED that is condensed on a front surface may be improved. In the specification, the diagonal direction may be diagonal in the vertical direction or diagonal in the left-right direction, as described with reference to FIG. 3.

The coating layer CTL may be disposed on the light control layer OSL. The coating layer CTL may cover the lens layer LEL. The coating layer CTL may have a refractive index lower than that of the lens LENS. The coating layer CTL having a relatively low refractive index may be disposed on the lens LENS having a high refractive index, refraction of light passing through the lens LENS may be effectively controlled, and thus condensing efficiency in a front surface direction may be improved.

Referring to FIG. 8, the light traveling in the diagonal direction (e.g. diagonal in the vertical direction) among the light emitted from the light emitting element ED may be refracted to a front surface by the patterns PAT defined in the boundary surface between the first low refractive layer LRL1 and the high refractive layer HRL. As described above, the high refractive layer HRL may have a higher refractive index than that of the first low refractive layer LRL1. Accordingly, the light that is emitted from the light emitting element ED, travels in the diagonal direction, and reaches the upper surface of the first low refractive layer LRL1 may be refracted in the boundary surface between the first low refractive layer LRL1 and the high refractive layer HRL, and thus a condensing effect in the front surface direction (or the third direction DR3) may be achieved. Accordingly, viewing angle limitation characteristics and front light emitting efficiency of the display area DA (see FIG. 3) may be improved.

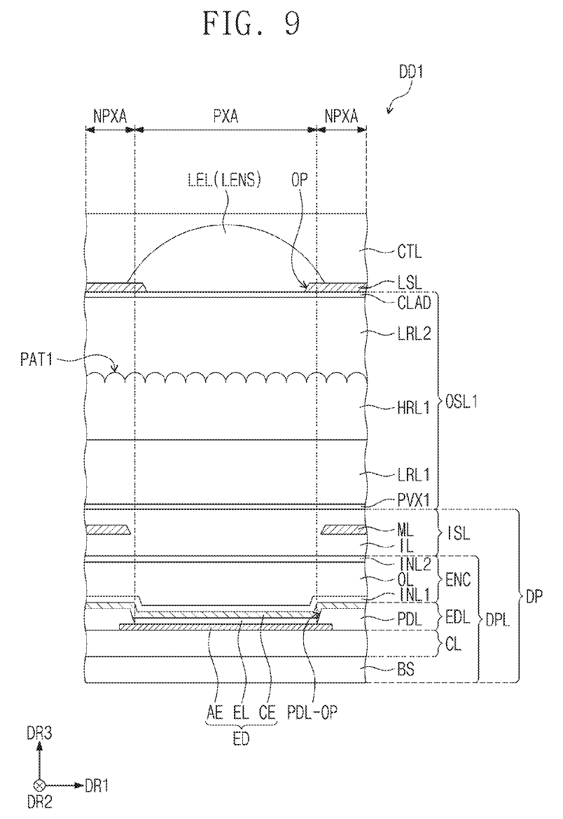

FIG. 9 is a cross-sectional view of the portion of the display device according to an aspect of the present disclosure. In description with reference to FIG. 9, the same/similar reference numerals are used for the same/similar components as those described in FIGS. 7 and 8, and duplicated descriptions thereof will be omitted.

Referring to FIG. 9, a plurality of patterns PAT1 may be defined on the upper surface of the high refractive layer HRL. Each of the patterns PAT1 may be a convex pattern protruding in a direction (or the third direction DR3) toward the light shielding layer LSL.

Light traveling in the diagonal direction among the light emitted from the light emitting element ED may be refracted to a front surface by the patterns PAT1 defined in a boundary surface between the high refractive layer HRL and the second low refractive layer LRL2. As described above, the second low refractive layer LRL2 may have a lower refractive index than that of the high refractive layer HRL. Accordingly, the light that is emitted from the light emitting element ED, travels in the diagonal direction (or the vertical direction), and reaches the upper surface of the high refractive layer HRL may be refracted in the boundary surface between the high refractive layer HRL and the second low refractive layer LRL2, and thus a condensing effect in the third direction DR3 may be achieved. Accordingly, the viewing angle limitation characteristics and the front light emitting efficiency of the display area DA (see FIG. 3) may be improved.

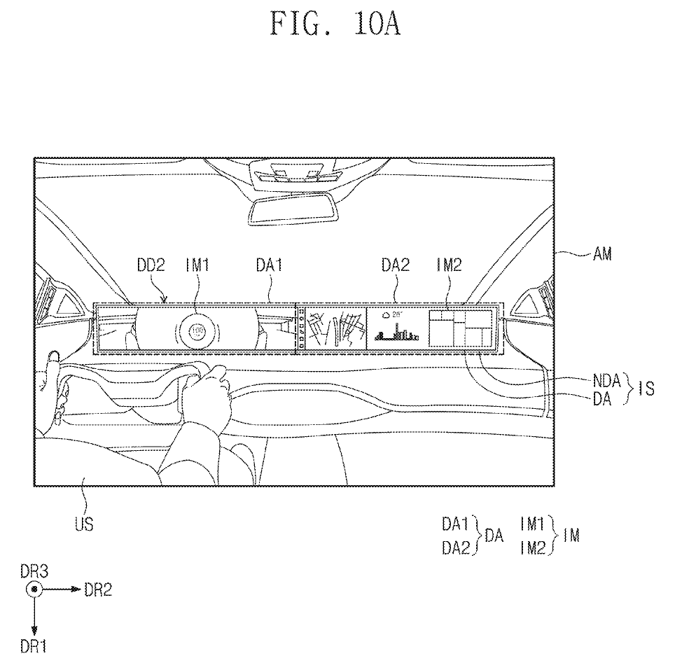

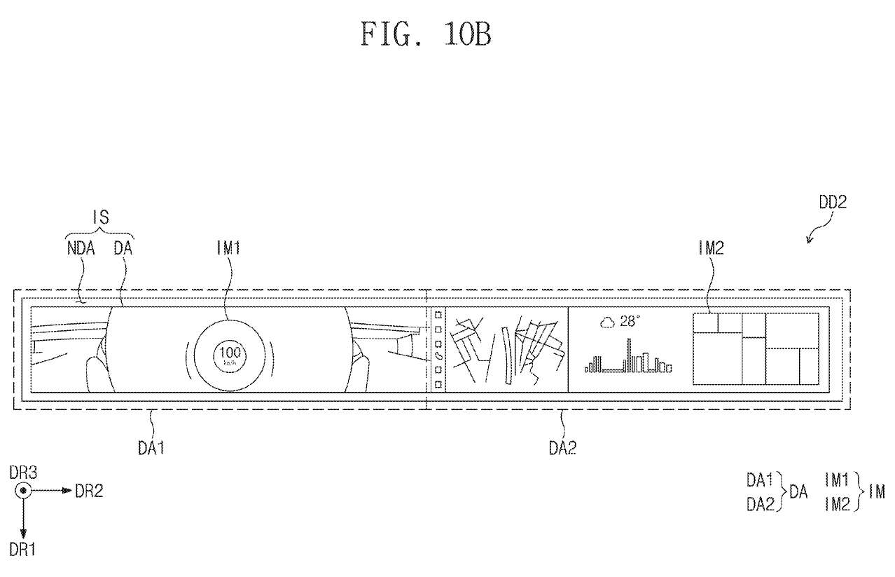

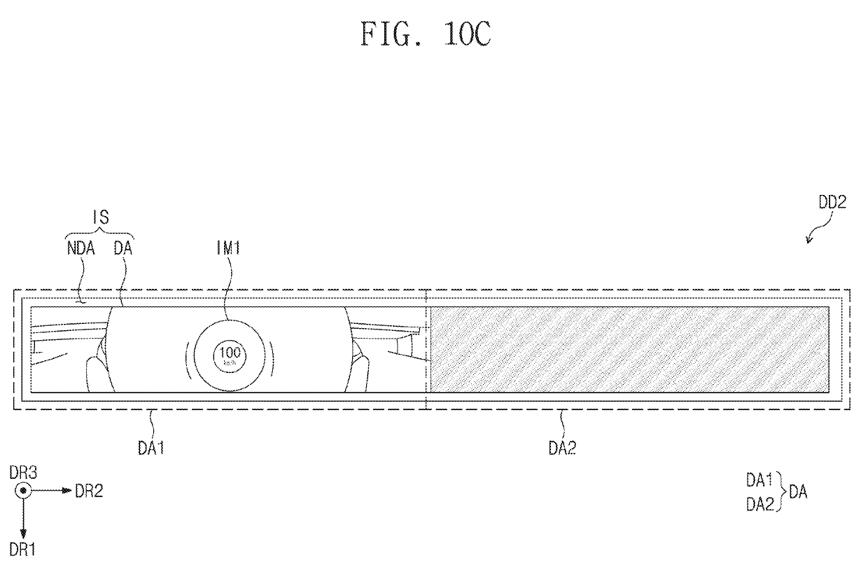

FIG. 10A is a view illustrating the interior of the vehicle AM in which the display device DD according to an aspect of the present disclosure is disposed. FIG. 10B is a view illustrating images IM1 and IM2 visually recognized from the driver seat when the display device DD according to an aspect of the present disclosure operates in a first mode. FIG. 10C is a view illustrating the first image IM1 visually recognized from the driver seat when the display device DD according to an aspect of the present disclosure operates in a second mode.

Referring to FIG. 10A, the display area DA may include a first display area DA1 and a second display area DA2. The first display area DA1 may be disposed at a position facing the driver seat, and the second display area DA2 may be disposed at a position facing a passenger seat. The first display area DA1 may provide the first image IM1, and the second display area DA2 may provide the second image IM2. For example, as described with reference to FIG. 3, the first image IM1 may display speed information, vehicle condition information, and vehicle internal operation information, and the second image IM2 may display not only information required for driving such as navigation information but also various pieces of information not related to driving. In this case, the first display area DA1 may correspond to the display area DA of FIG. 3.

In an aspect, a display device DD2 may operate in the first mode or the second mode. The first mode and the second mode may be a state in which viewing angles of the first display area DA1 and the second display area DA2 are selectively controlled. In an aspect, the display device DD2 may perform a control so that the first display area DA1 and the second display area DA2 have the same viewing angle in the first mode, and perform a control so that the first display area DA1 and the second display area DA2 have different viewing angles in the second mode. In an aspect, the second display area DA2 may be an area in which a viewing angle is controlled according to a mode. Accordingly, the second display area DA2 may operate in a normal mode of displaying a screen in the left-right direction DR2 at a first viewing angle AG1 in the first mode or operate in a viewing angle control mode of displaying a screen at a second viewing angle AG2 smaller than the first viewing angle AG1 in the second mode.

Referring to FIG. 10B, when the display device DD operates in the first mode, the second image IM2 of the second display area DA2 may be visually recognized by the driver US. The first mode may be operated during stopping. That is, in the first mode, the driver US may also view information not required for driving.

Referring to FIG. 10C, when the display device DD operates in the second mode, the second image IM2 of the second display area DA2 may not be visually recognized by the driver US. The second mode may be operated during traveling. The driver US may view only the information required for driving and may not view the information not required for driving due to viewing angle limitations. FIG. 10C illustrates, by way of example, that the entire second display area DA2 is not visually recognized by the driver US, but the present disclosure is not limited thereto, and a partial area of the second display area DA2 may be visually recognized, and the other partial area thereof may not be visually recognized. For example, only the information (e.g., navigation information) required for driving of a partial area of the second display area DA2, which is disposed adjacent to the first display area DA1, may be viewed, and the information not required for driving of the other partial area spaced apart from the first display area DA1 may not be viewed. An area, in which a first light emitting part EP1 and a second light emitting part EP2 which will be described below are operated, may be adjusted to adjust an area of the second display area DA2, which may be visually recognized by the driver US, in the second mode.

The display device DD may selectively operate in one of the first mode and the second mode. Switching between the first mode and the second mode may be performed when the user adjusts the mode in settings, the vehicle drives or stops, or a specific application is executed.

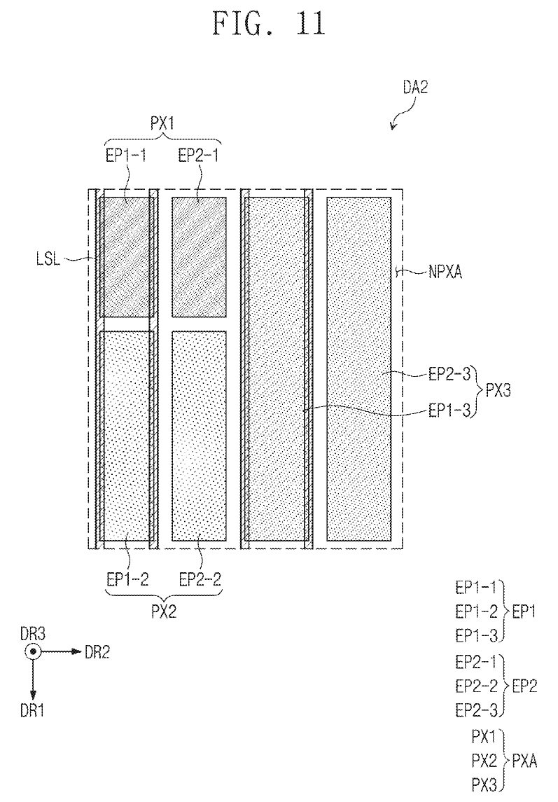

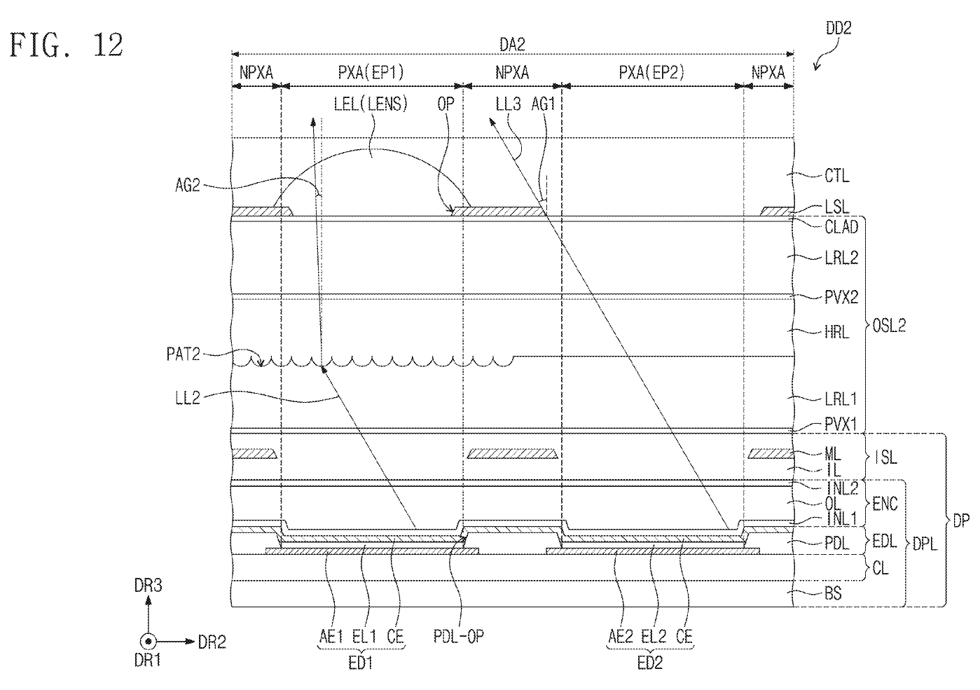

FIG. 11 is an enlarged plan view of a partial area of a display panel according to an aspect of the present disclosure. FIG. 12 is a cross-sectional view of a portion of the display device DD2 according to an aspect of the present disclosure. FIG. 11 is a plan view illustrating the first light emitting part EP1, the second light emitting part EP2, and the light shielding layer LSL included in the display panel DP (see FIG. 5A) with respect to the second display area DA2 (see FIG. 10A) when viewed in the third direction DR3, and FIG. 12 is a cross-sectional view illustrating the partial area of the second display area DA2 according to an aspect of the present disclosure. In description with reference to FIGS. 11 to 12, the same/similar reference numerals are used for the same/similar components as those described in FIGS. 7 to 10, and duplicated descriptions thereof will be omitted.

Referring to FIG. 11, a plurality of pixels PX1, PX2, and PX3 may be arranged on the display panel DP (see FIG. 5A). The plurality of pixels PX1, PX2, and PX3 may include the first color pixel PX1, the second color pixel PX2, and the third color pixel PX3. The first color pixel PX1 may provide first color light, e.g., red light. The second color pixel PX2 may provide second color light, e.g., green light. The third color pixel PX3 may provide third color light, e.g., blue light.

The second color pixel PX2 may be disposed to be spaced apart from the first color pixel PX1 in the first direction DR1. The third color pixel PX3 may be disposed to be spaced apart from the first color pixel PX1 and the second color pixel PX2 in the second direction DR2. However, arrangement of the first color pixel PX1, the second color pixel PX2, and the third color pixel PX3 is not limited thereto.

FIG. 11 illustrates that one pixel unit PXU includes the three pixels PX1, PX2, and PX3 as an example. However, the one pixel unit PXU may include two pixels or four or more pixels. Further, FIG. 11 illustrates that an area of the third color pixel PX3 is the largest and an area of the first color pixel PX1 is the narrowest, but the present disclosure is not limited thereto, and areas of the first color pixel PX1, the second color pixel PX2, and the third color pixel PX3 may be changed. Further, FIG. 11 illustrates that planar shapes of the first color pixel PX1, the second color pixel PX2, and the third color pixel PX3 are rectangular, but the planar shapes of the first color pixel PX1, the second color pixel PX2, and the third color pixel PX3 are not limited thereto.

In an aspect, the second display area DA2 may include the first light emitting part EP1 and the second light emitting part EP2. The first light emitting part EP1 and the second light emitting part EP2 may be alternately arranged in the second direction DR2. The first light emitting part EP1 and the second light emitting part EP2 may operate differently from each other. In detail, both the first light emitting part EP1 and the second light emitting part EP2 may be operated or only one thereof may be operated. For example, in the first mode, the first light emitting part EP1 may not operate, and only the second light emitting part EP2 may operate, and in the second mode, only the first light emitting part EP1 may operate, and the second light emitting part EP2 may not operate.

The first light emitting part EP1 may include a (1-1)^{th} light emitting portion EP1-1 disposed in the first color pixel PX1, a (1-2)^{th} light emitting portion EP1-2 disposed in the second color pixel PX2, and a (1-3)^{th} light emitting portion EP1-3 disposed in the third color pixel PX3. The second light emitting part EP2 may include a (2-1)^{th} light emitting portion EP2-1 disposed in the first color pixel PX1, a (2-2)^{th} light emitting portion EP2-2 disposed in the second color pixel PX2, and a (2-3)^{th} light emitting portion EP2-3 disposed in the third color pixel PX3.

The (2-1)^{th} light emitting portion EP2-1 may be disposed to be spaced apart from the (1-1)^{th} light emitting portion EP1-1 in the second direction DR2. The (2-2)^{th} light emitting portion EP2-2 may be disposed to be spaced apart from the (1-2)^{th} light emitting portion EP1-2 in the second direction DR2. The (2-3)^{th} light emitting portion EP2-3 may be disposed to be spaced apart from the (1-3)^{th} light emitting portion EP1-3 in the second direction DR2. The (1-2)^{th} light emitting portion EP1-2 may be disposed to be spaced apart from the (1-1)^{th} light emitting portion EP1-1 in the first direction DR1. The (2-2)^{th} light emitting portion EP2-2 may be disposed to be spaced apart from the (2-1)^{th} light emitting portion EP2-1 in the first direction DR1.

Meanwhile, this is illustrated by way of example, an arrangement relationship between the light emitting parts EP1 and EP2 may be variously changed according to shapes thereof, and the present disclosure is not limited to any particular arrangement.

The light shielding layer LSL may be disposed on the light emitting parts EP1 and EP2. The opening OP vertically overlapping the light emitting parts EP1 and EP2 may be defined in the light shielding layer LSL. The light shielding layer LSL may vertically overlap at least a portion of the first light emitting part EP1 and may not vertically overlap the second light emitting part EP2. An area of the opening OP vertically overlapping the first light emitting part EP1 may be smaller than an area of the opening OP vertically overlapping the second light emitting part EP2.

Referring to FIG. 12, the light emitting element ED may be provided as a plurality of light emitting elements ED. The light emitting element ED may include a first light emitting element ED1 disposed in the first light emitting part EP1 and a second light emitting element ED2 disposed in the second light emitting part EP2.

A light control layer OSL2 may include a first low refractive layer LRL1, the second low refractive layer LRL2, the high refractive layer HRL, the first inorganic protective film PVX1, the second inorganic protective film PVX2, and the third inorganic protective film CLAD.

In an aspect, the first low refractive layer LRL1 may include a pattern part including the plurality of patterns PAT and a flat part having a flat upper surface. The pattern part may vertically overlap the first light emitting element ED1 disposed in the first light emitting part EP1. The flat part may vertically overlap the second light emitting element ED2 disposed in the second light emitting part EP2.

The lens layer LEL may be disposed on the light control layer OSL2. The lens layer LEL may include the lens LENS that overlaps the opening OP defined in the light shielding layer LSL. In an aspect, the lens LENS may be disposed in the first light emitting part EP1 and may not be disposed in the second light emitting part EP2. That is, the lens LENS may vertically overlap the first light emitting element ED1 on a plane and may not vertically overlap the second light emitting element ED2.

In an aspect, the second light LL2 traveling in the diagonal direction (or the left-right direction) among the light emitted from the first light emitting element ED1 may be refracted in the third direction DR3 by the patterns PAT defined in the boundary surface between the first low refractive layer LRL1 and the high refractive layer HRL. On the other hand, second light LL2 traveling in the diagonal direction among the light emitted from the second light emitting element ED2 may not be refracted in the boundary surface between the first low refractive layer LRL1 and the high refractive layer HRL.

According to the present disclosure, as the light emitted from the first light emitting element ED1 passes through the pattern PAT2 and the lens LENS, the amount of light emitted in the second direction DR2 or an opposite direction to the second direction DR2 may be decreased. That is, light displayed on the first light emitting part EP1 may be light having the limited viewing angle AG2 in the second direction DR2 or the opposite direction to the second direction DR2.

Unlike this, the flat portion of interface between LRL1 and HRL and the lens LENS do not interfere in the light emitted from the second light emitting element ED2, and thus the amount of light emitted in the second direction DR2 or the opposite direction to the second direction DR2 may be relatively large. That is, light displayed by the second light emitting part EP2 may have an unrestricted viewing angle in the second direction DR2 or the opposite direction to the second direction DR2 compared to the light emitted by the first light emitting part EP1.

In the first mode, the first light emitting element ED1 is driven, the second light emitting element ED2 is not driven, and thus the display device may display an image having a limited viewing angle. Thus, image visibility in the second direction DR2 or the opposite direction to the second direction DR2 may be reduced, front light efficiency may be improved, and thus a private mode may be easily implemented.

Further, in the second mode, the first light emitting element ED1 is not driven, the second light emitting element ED2 is driven, and thus the display device may display an image having an unrestricted viewing angle. For example, as illustrated in FIGS. 10A to 10C, when the display device is installed such that the second direction DR2 and the opposite direction to the second direction DR2 are the left-right direction, the display device may provide the second display area DA2 that is visible or invisible to the driver US (see FIG. 10A) depending on mode selection. Thus, a display device capable of easily changing between a private mode and a normal mode according to selection of the user may be provided.

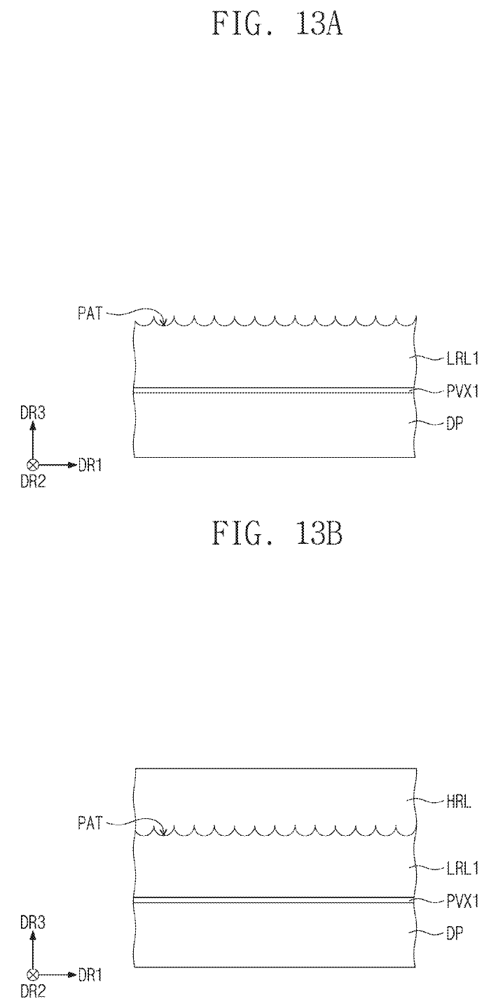

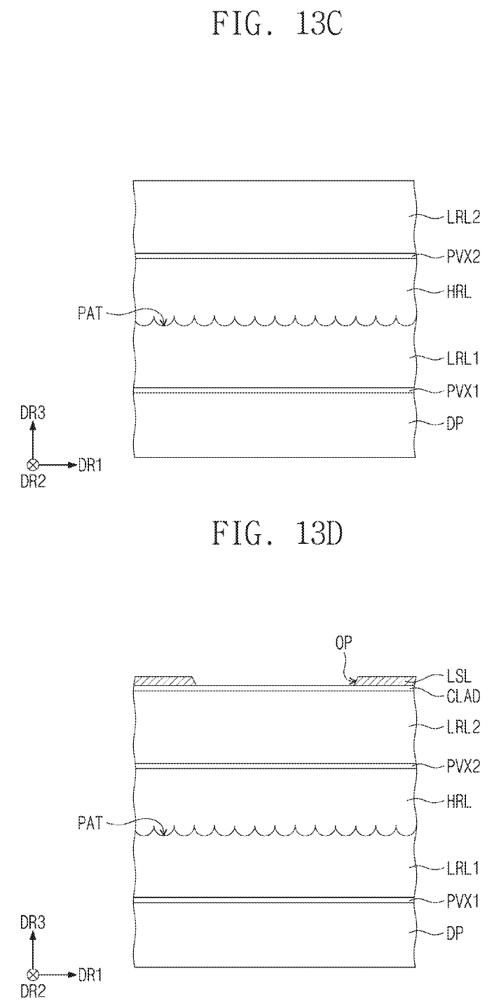

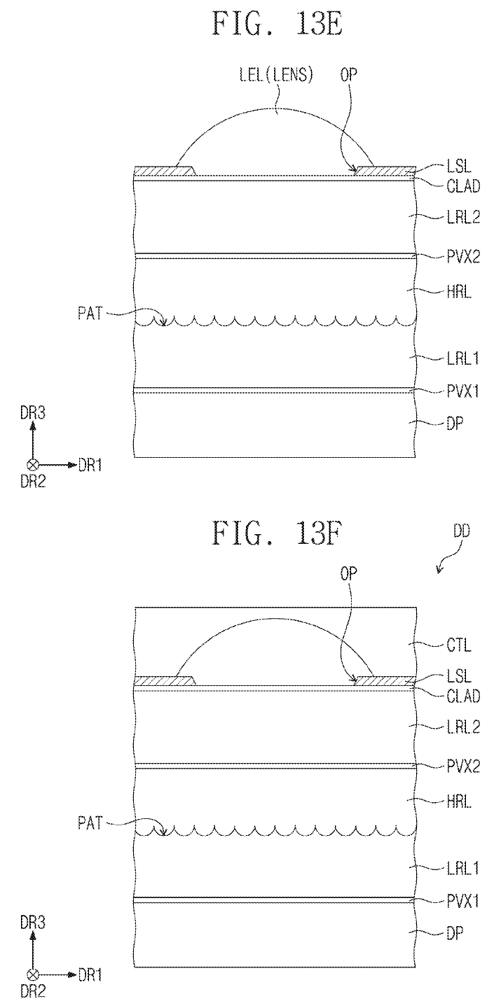

FIGS. 13A to 13F are cross-sectional views illustrating steps for manufacturing a display device according to an aspect of the present disclosure. In description with reference to FIGS. 13A to 13F, the same/similar reference numerals are used for the same/similar components as those described in FIGS. 7 to 12, and duplicated descriptions thereof will be omitted.

For convenience, FIGS. 13A to 13F illustrate an area corresponding to FIG. 7, and detailed components of the display panel DP are omitted.

Referring to FIG. 13A, the first inorganic protective film PVX1 and the first low refractive layer LRL1 may be sequentially formed on the display panel DP.

The first inorganic protective film PVX1 may be deposited to cover an upper surface of the display panel DP. The first inorganic protective film PVX1 may be formed by depositing an inorganic material by a sputtering method or a chemical vapor deposition method. For example, the first inorganic protective film PVX1 may include a silicon oxide, a silicon nitride, or a transparent conductive oxide.

The first low refractive layer LRL1 may be formed on the first inorganic protective film PVX1. The first low refractive layer LRL1 may be formed by applying and curing a transparent organic material. The first low refractive layer LRL1 may be formed through inkjet coating. The refractive index of the first low refractive layer LRL1, measured at a wavelength of 632 nm, may be smaller than or equal to 1.54. In this case, the transparent organic material may be the same material as the organic layer OL of the encapsulation layer ENC.

The plurality of patterns PAT may be formed on the upper surface of the first low refractive layer LRL1. In this case, the plurality of patterns PAT may be formed through a dry etching process or a photoresist process.

Referring to FIG. 13B, the high refractive layer HRL may be formed on the first low refractive layer LRL1. The high refractive layer HRL may be formed by applying and curing a transparent organic material. The high refractive layer HRL may be formed through inkjet coating. The high refractive layer HRL may include a transparent organic material having a refractive index higher than that of the first low refractive layer LRL1. However, this has been described by way of example, the first low refractive layer LRL1 may be formed of various materials as long as the first low refractive layer LRL1 has the above-described refractive index and is optically transparent, and the present disclosure is not limited to any particular materials.

The patterns PAT formed at the boundary surface between the high refractive layer HRL and the first low refractive layer LRL1 may be stably covered, so that the optical focus of the patterns PAT defined in the boundary surface may be stabilized, unnecessary light scattering may be suppressed, and thus condensing performance may be improved.

Referring to FIG. 13C, the second inorganic protective film PVX2 and the second low refractive layer LRL2 may be sequentially formed on the high refractive layer HRL.

The second inorganic protective film PVX2 may be deposited to cover the upper surface of the high refractive layer HRL. The second inorganic protective film PVX2 may be formed by depositing an inorganic material by a sputtering method or a chemical vapor deposition method. For example, the second inorganic protective film PVX2 may include a silicon oxide, a silicon nitride, or a transparent conductive oxide.

The second low refractive layer LRL2 may be formed on the second inorganic protective film PVX2. The second low refractive layer LRL2 may be formed by applying and curing a transparent organic material. The second low refractive layer LRL2 may be formed through inkjet coating. The refractive index of the second low refractive layer LRL2, measured at a wavelength of 632 nm, may be smaller than or equal to 1.54. In this case, the organic material may be the same material as the organic layer OL of the encapsulation layer ENC. The second low refractive layer LRL2 may be formed on the second inorganic protective film PVX2 and thus may be more stably applied on the high refractive layer HRL.

Referring to FIG. 13D, the third inorganic protective film CLAD and the light shielding layer LSL may be sequentially formed on the second low refractive layer LRL2.

The light shielding layer LSL may be formed on the second low refractive layer LRL2. In the light shielding layer LSL, after a light shielding material is applied and cured onto the upper surface of the second low refractive layer LRL2, the cured light shielding material may be patterned, and thus the opening OP overlapping the light emitting parts EP1 and EP2 (see FIG. 7) may be formed. In this case, the light shielding material may be patterned by a photoresist process or patterned through a patterned hard mask.

Referring to FIGS. 13E and 13F, the lens layer LEL and the coating layer CTL may be sequentially formed on the light shielding layer LSL.

The lens layer LEL may be formed to overlap the opening OP formed in the light shielding layer LSL. The lens layer LEL may be formed by applying and curing a transparent organic material onto the third inorganic protective film CLAD and the light shielding layer LSL and then patterning the cured organic material. In this case, the transparent organic material may be patterned by a photoresist process. In this case, a refractive index of the transparent organic material, measured at a wavelength of 632 nm, may be greater than or equal to 1.63.

The coating layer CTL may be formed to cover the lens layer LEL. The coating layer CTL may be formed by applying and curing a transparent organic material. The coating layer CTL may be formed through inkjet coating. A refractive index of the coating layer CTL, measured at a wavelength of 632 nm, may be smaller than or equal to 1.54.

According to the present disclosure, a light control layer including an organic layer including concave or convex patterns and a lens layer disposed on the light control layer may be provided to a display area of a display device disposed at a position facing a driver seat, and thus the path of light emitted from a light emitting element may be limited to prevent light from traveling in a vertical direction. That is, a path of the light provided from the light emitting element in a vertical direction may be limited, the light fails to reach a windshield of a vehicle, and thus safety of a driver may be secured.

Further, a display device having a light emitting element that vertically overlaps the patterns and the lens and a light emitting element that does not vertically overlap the patterns and the lens are arranged in a display area disposed at a position facing a passenger seat, and thus a private mode and a normal mode may be easily switched according to selection of a user may be provided.

Although the description has been made above with reference to aspects of the present disclosure, it may be understood that those skilled in the art or those having ordinary knowledge in the art may variously modify and change the present disclosure without departing from the spirit and technical scope of the present disclosure. It should therefore be understood that the aspects described above are exemplary in all respects and are not intended to be limiting.

What is claimed is:

1. An electronic device comprising:
a plurality of light emitting parts each configured to emit light;
an encapsulation layer covering the light emitting parts;
a lens layer disposed on the encapsulation layer, the lens layer comprising a plurality of lenses;
light shielding layer, on which a plurality of openings respectively overlapping the light emitting parts are defined, and the plurality of lenses respectively overlapping the openings;
a coating layer covering the lens layer; and
a light control layer disposed between the lens layer and the encapsulation layer; the light control layer including a first low refractive layer, a high refractive layer, and a second low refractive layer that are sequentially arranged on the light emitting parts and are made of organic materials,
wherein an upper surface or a lower surface of the high refractive layer includes a plurality of convex patterns, and
wherein each of the plurality of lenses vertically overlaps two or more of the convex patterns.

2. The electronic device of claim 1, further comprising:
an inorganic protective film disposed between the high refractive layer and the second low refractive layer,
wherein the convex patterns are spaced apart from the inorganic protective film, are defined on the lower surface of the high refractive layer, and are in contact with the first low refractive layer.

3. The electronic device of claim 1, wherein the convex patterns are spaced apart from the first low refractive layer, are defined on the upper surface of the high refractive layer, and are in contact with the second low refractive layer.

4. The electronic device of claim 1, wherein a maximum width of each of the lenses is 10 times or less than a maximum width of each of the convex patterns.

5. The electronic device of claim 1, wherein a recessed depth of each of the convex patterns is 0.5 times or less than a maximum width of each of the convex patterns.

6. The electronic device of claim 1, wherein the light shielding layer vertically overlaps at least some of the convex patterns.

7. The electronic device of claim 1, wherein each of the lenses has a refractive index higher than those of the second low refractive layer and the coating layer.

8. The electronic device of claim 1, wherein the encapsulation layer includes a first inorganic layer, an organic layer, and a second inorganic layer, and
wherein the first low refractive layer includes the same material as the organic layer.

9. The electronic device of claim 1, further comprising:
a sensor layer disposed between the light control layer and the encapsulation layer.

10. The electronic device of claim 1, wherein a refractive index of the high refractive layer is greater than or equal to 1.63, and refractive indexes of the first low refractive layer, the second low refractive layer, and the coating layer are smaller than or equal to 1.54.

11. The electronic device of claim 1, wherein the light emitting parts include a first light emitting part and a second light emitting part, and
wherein the lenses and the plurality of patterns vertically overlap the first light emitting part and do not vertically overlap the second light emitting part.

12. An electronic device comprising:
a display panel including a plurality of light emitting parts and an encapsulation layer covering the light emitting parts;
a processor configured to provide image data to the display panel;
a light control layer disposed on the display panel, the light control layer including a first low refractive layer, a second low refractive layer disposed on the first low refractive layer, and a high refractive layer disposed between the first low refractive layer and the second low refractive layer, the high refractive layer having a refractive index higher than a refractive index of the first low refractive layer and a refractive index of the second low refractive layer;
a window disposed on the light control layer;
a light shielding layer disposed on the second low refractive layer;
an opening defined within the light shielding layer;
a lens overlapping the opening and disposed on an upper surface of the second low refractive layer; and
a coating layer configured to cover the light shielding layer and the lens,
wherein an upper surface of the first low refractive layer or of the high refractive layer includes a plurality of concave or convex patterns, and
wherein a maximum width of the lens is greater than a maximum width of each of the patterns.

13. The electronic device of claim 12, wherein the patterns are defined on the upper surface of the first low refractive layer, and
wherein each of the patterns is a concave pattern recessed toward the display panel.

14. The electronic device of claim 13, wherein the maximum width of the lens is 10 times or less than a maximum width of the concave pattern.

15. The electronic device of claim 13, wherein a recessed depth of the concave pattern is 0.5 times or less than a width of the concave pattern.

16. The electronic device of claim 13, further comprising:
an inorganic film disposed on the high refractive layer.

17. The electronic device of claim 12, wherein the patterns are defined on the upper surface of the high refractive layer, and
wherein each of the patterns is a convex pattern protruding toward the light shielding layer.

18. The electronic device of claim 17, wherein the convex pattern is in contact with the second low refractive layer.

19. The electronic device of claim 12, wherein the encapsulation layer includes a first inorganic layer, an organic layer, and a second inorganic layer, and
wherein the first low refractive layer includes the same material as the organic layer.

20. The electronic device of claim 12, wherein a refractive index of the high refractive layer is greater than or equal to 1.63, and refractive indexes of the first low refractive layer, the second low refractive layer, and the coating layer are smaller than or equal to 1.54.
